(19) United States
(12) Patent Application Publication
(10) Pub. No.: US 2026/0343914 A1
(43) Pub. Date: Oct. 29, 2026

(54) BIPOLAR TRANSISTOR IN WIRE CONFIGURATION

(71) Applicant: STMicroelectronics International N.V., Geneva (CH)

(72) Inventor: Pascal CHEVALIER, Chapareillan (FR)

(73) Assignee: STMicroelectronics International N.V., Geneva (CH)

(21) Appl. No.: 19/653,640

(22) Filed: Apr. 21, 2026

(30) Foreign Application Priority Data
Apr. 23, 2025 (FR) FR2504310

(51) Int. Cl. H10D 10/40; H10D 10/80; H10D 62/10; H10D 62/83; H10D 62/832; H10D 84/60; H10D 10/01

(52) U.S. Cl. CPC H10D 10/40; H10D 10/821; H10D 62/124; H10D 62/83; H10D 62/832; H10D 84/641; H10D 10/021; H10D 10/051

(57) ABSTRACT

A bipolar transistor includes: a semiconductor stack having a three-dimensional wire shape successively comprising a collector portion, a base portion and an emitter portion. A lower insulating layer at least partly surrounds and is in contact with a lateral edge of the collector portion. An intermediate doped layer at least partly surrounds and is in contact with a lateral edge of the base portion. An upper insulating portion at least partly surrounds and is in contact with a lateral edge of the emitter portion.

### PRIORITY CLAIM

This application claims the priority benefit of French Application for Patent No. FR2504310, filed on Apr. 23, 2025, the content of which is hereby incorporated by reference in its entirety to the maximum extent allowable by law.

### TECHNICAL FIELD

The present description relates in general to bipolar transistors in a wire configuration, whether homojunction or heterojunction, and their manufacturing methods.

### BACKGROUND

Bipolar transistors, and particularly heterojunction bipolar transistors (HBT) of the SiGe type, are known to have particularly good performance in high-frequency uses, in particular in the millimeter and terahertz frequency range. Such transistors have high performance in terms of gain, noise in 1/f, breakdown voltage, etc.

In general, a bipolar transistor corresponds to two PN diodes facing each other. It includes: an emitter doped according to a first type of conductivity, where the carriers are created and injected into a base; the base doped according to a second type opposite to the first type, where the control of the currents of the transistor is carried out; and a collector doped according to the first type, where the carriers are collected.

In order to improve performance, a bipolar transistor configuration having a three-dimensional wire shape is desired.

### SUMMARY

According to one aspect of the present disclosure, a bipolar transistor in a three-dimensional wire configuration, the structure of which can be created with the conventional methods of microelectronics, is proposed.

For this, the bipolar transistor comprises: a substrate made of a crystalline semiconductor material and having an upper face; a lower doped region located in the substrate and flush with the upper face of the substrate; a semiconductor stack, having a three-dimensional wire shape, extending from the substrate and successively comprising: a collector portion resting on and in contact with the lower doped region; a base portion resting on and in contact with the collector portion; and an emitter portion resting on and in contact with the base portion; a lower insulating layer resting on the substrate and at least partly surrounding and in contact with a lateral edge of the collector portion; an intermediate doped layer made of a crystalline semiconductor material and resting on the lower insulating layer at least partly surrounding and in contact with a lateral edge of the base portion; and an upper insulating portion at least partially surrounding and in contact with a lateral edge of the emitter portion.

According to one embodiment, the material of the lower doped region and the material(s) of the semiconductor stack are monocrystalline.

According to one embodiment, the lower doped region, the semiconductor stack, and the intermediate doped layer are made from silicon.

According to one embodiment, the bipolar transistor includes an epitaxial regrowth layer, resting on the lower insulating layer, surrounding the base portion while being laterally spaced apart, and made of a crystalline, preferably monocrystalline, semiconductor material, the intermediate doped layer resting on and in contact with the epitaxial regrowth layer.

According to one embodiment, the lower insulating layer is in contact with the collector portion over its entire height and its entire periphery, and is in contact with a lower part of the lateral edge of the base portion over its entire periphery, the intermediate doped layer thus being electrically insulated from the collector portion.

According to one embodiment, the upper insulating portion is in contact with the emitter portion over its entire height and its entire periphery, and is in contact with an upper part of the lateral edge of the base portion over its entire periphery, the intermediate doped layer thus being electrically insulated from the emitter portion.

According to one embodiment, the semiconductor stack has constant transverse dimensions over its entire height.

According to one embodiment, the bipolar transistor includes a filling layer, made of an electrically insulating material, through which extend: a collector contact coming into contact with the lower doped region; a base contact coming into contact with the intermediate doped layer; and an emitter contact coming into contact with the emitter portion.

According to one embodiment, the lower doped region includes, on its upper face, a non-silicided part on which the semiconductor stack is in contact, and a silicided part on which the collector contact is in contact; the intermediate doped layer has, on its upper face, a silicided part on which the base collector is in contact; and the emitter portion has, on its upper face, a silicided part on which the emitter collector is in contact.

According to one embodiment, the base portion is made from silicon-germanium.

According to another aspect, an integrated circuit including a plurality of bipolar transistors according to any one of the preceding features is proposed.

According to another aspect, a method for manufacturing a bipolar transistor is proposed, including the following steps: creating a lower doped region located in a substrate made of a crystalline semiconductor material and having an upper face that is flush with the upper face of the substrate; creating a lower insulating layer on the substrate and the lower doped region; creating an epitaxial regrowth layer resting on the lower insulating layer and having a through-hole; creating a sacrificial layer covering the epitaxial regrowth layer and the through-hole; creating an upper insulating layer covering the sacrificial layer; creating a cavity extending down to the lower doped region and passing through the through-hole; creating via epitaxy a semiconductor stack in the cavity, having a three-dimensional wire shape, extending from the substrate and successively comprising: a collector portion resting on and in contact with the lower doped region; a base portion resting on and in contact with the collector portion; and an emitter portion resting on and in contact with the base portion; creating an upper insulating portion at least partly surrounding and in contact with a lateral edge of the emitter portion, by localized etching of the upper insulating layer, the latter being completed so as to cover the emitter portion; selectively removing the sacrificial layer to free a surface of the epitaxial regrowth layer and a surface of the base portion; and creating an intermediate doped layer made of a crystalline semiconductor material by epitaxy starting from the free surface of the epitaxial regrowth layer and the free surface of the base portion.

According to one embodiment, the semiconductor stack is created in a single epitaxy step.

According to one embodiment, during the step of creating the lower insulating layer, a first sub-layer is deposited on the substrate and the lower doped region; then a second sub-layer is transferred and bonded to the first sub-layer, the second sub-layer being coated on its opposite face by the epitaxial regrowth layer, the latter being made of a monocrystalline material.

According to one embodiment, the method further includes the following steps: creating, on an upper face of the lower doped region, a non-silicided part on which the semiconductor stack is in contact and a silicided part; creating, on an upper face of the intermediate doped layer, a silicided part; creating, on an upper face of the emitter portion, a silicided part; creating a filling layer, made of an electrically insulating material, covering the semiconductor stack, the intermediate doped layer and the lower insulating layer; creating, through the filling layer, a collector contact coming in contact with the silicided part of the lower doped region; creating a base contact coming in contact with the silicided part of the intermediate doped layer; and creating an emitter contact coming in contact with the silicided part of the emitter portion.

### BRIEF DESCRIPTION OF THE DRAWINGS

Other advantages and features of the invention will become apparent upon examining the detailed description of embodiments and implementations, in no way limiting, and the appended drawings in which:

FIG. 1 is a schematic and partial view of an integrated circuit including at least one bipolar transistor in a wire configuration; and

FIGS. 2A-2O illustrate various steps of a method for manufacturing an integrated circuit including at least one bipolar transistor in a wire configuration.

### DETAILED DESCRIPTION

In the drawings and in the rest of the description, the same references represent identical or similar elements. In addition, the various elements are not shown to scale so as to favour the clarity of the drawings. Moreover, the various embodiments and alternatives are not exclusive of each other and can be combined with each other.

Unless indicated otherwise, the terms “substantially”, “about”, “approximately” mean to within 10%, and preferably to within 5%. Moreover, the terms “between… and…” and equivalents mean that the limits are included, unless stated otherwise.

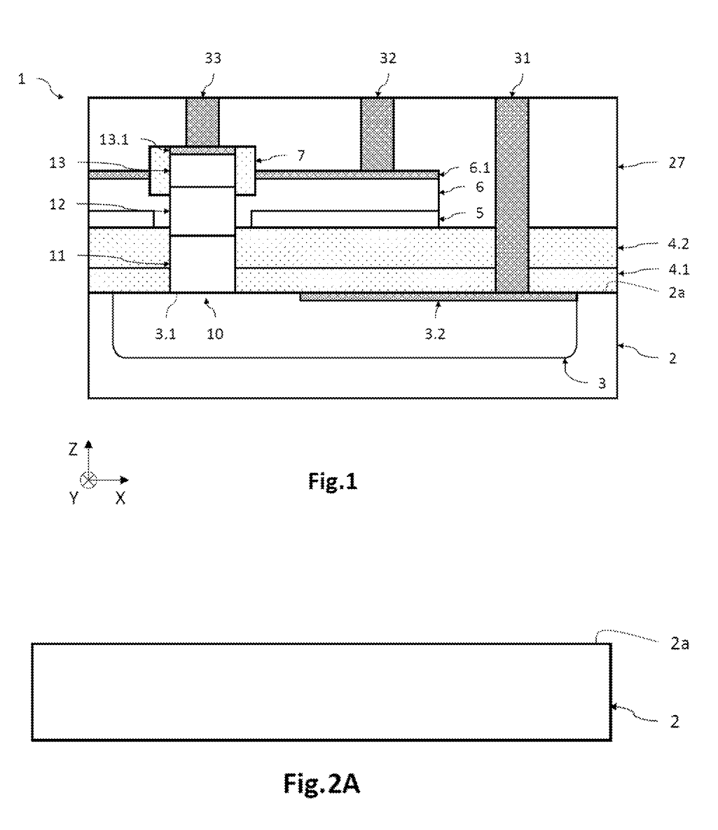

FIG. 1 is a schematic and partial view of an integrated circuit including bipolar transistors in a wire configuration according to one embodiment. Here, only one bipolar transistor 1 is shown for the sake of clarity of the drawings.

Here and for the remainder of the description, a three-dimensional right-handed coordinate system XYZ is defined, in which the plane XY is parallel to the main plane of the bipolar transistor 1, and in which the axis Z is oriented according to the thickness of the latter. Furthermore, the terms “lower” and “upper” are meant as relative to an increasing positioning in the direction +Z.

The bipolar transistor 1 here is homojunction and of the NPN type. However, it can be heterojunction on the one hand, for example of the Si/SiGe type, and it can be of the PNP type on the other hand.

The bipolar transistor 1 includes a substrate 2 made of a crystalline semiconductor material, and here preferably made of a monocrystalline material, for example made of silicon. The substrate 2 can be unintentionally doped or slightly doped of the P type or of the N type. It has a substantially flat upper face 2a. This can be a one-piece substrate, or a substrate formed by a stack of layers, in which case the upper layer defining the upper face is made here of monocrystalline silicon.

The bipolar transistor 1 includes a lower doped region 3 also referred to as an extrinsic collector layer. This extrinsic collector layer 3 is made of a crystalline semiconductor material, doped with the same type of conductivity as that of the collector portion 11 described below, here of the N type in the case of a bipolar transistor 1 of the NPN type.

The region 3 is located in the substrate 2 and is flush with a part of the upper face 2a thereof. The extrinsic collector layer 3 can be formed by localized ion implantation of dopants in the substrate 2.

In the case in which the extrinsic collector layer 3 is formed by deposition on a support substrate, the assembly formed by the support substrate and the extrinsic collector layer 3 is called substrate 2.

In the remainder of the description, the collector layer 3 and the base layer 6 will be referred to as “extrinsic” insofar as their characteristics are not modulated by the polarization conditions. However, the collector 11, base 12, and emitter 13 portions described below form the “intrinsic” portions of the bipolar transistor 1.

A non-silicided part 3.1 of the upper face 2a of the extrinsic collector layer 3 corresponds to a nucleation zone for the formation by epitaxial regrowth of the wire semiconductor stack 10 described below.

Another part 3.2 of the upper face 2a of the extrinsic collector layer 3 can be silicided, thus improving the resistance of contact with the collector contact 31.

The bipolar transistor 1 includes a semiconductor stack 10 formed by, successively starting from the substrate 2: a collector portion 11, a base portion 12, then an emitter portion 13.

This semiconductor stack 10 has a three-dimensional wire shape. In other words, it has an elongated shape that extends vertically along an axis Z substantially orthogonal to the plane XY of the substrate 2, and has transverse dimensions, in the plane XY, smaller than its longitudinal dimension. The term “wire” is a synonym of rod. It can be referred to as “nanowire” or “microwire” according to the value of the transverse dimensions. Below, reference will be made to a wire semiconductor stack.

For example, in the case of a “microwire”, the transverse dimensions can be approximately one micron, or even ten or one hundred microns, and in the case of a “nanowire”, they can be approximately ten to one hundred nanometers. The longitudinal dimension (or height) of the wire stack can be greater than 2 times, 5 times, or more, the transverse dimensions. The nanowire can thus have a diameter of approximately several tens of nanometers to about a hundred nanometers for a height of approximately several hundred nanometers.

Here, height refers to the longitudinal dimension along the axis Z of a portion 11, 12, 13 or of the wire stack 10, between the lower and upper faces of the element considered. These lower and upper faces are connected to each other by a peripheral lateral face that forms the lateral edge.

The transverse cross-section of the wire semiconductor stack 10, in the plane XY, can have various shapes, for example a circular, oval, polygonal, for example square, rectangular, hexagonal shape, among others. Preferably, the transverse cross-section is circular.

Here, a diameter is defined as a value associated with the perimeter of the wire stack at its transverse cross-section. This can be the diameter of a disc having the same surface area as the transverse cross-section of the wire semiconductor stack 10. The local diameter is the diameter of the wire semiconductor stack 10 at a given height thereof along the longitudinal axis Z.

Preferably, the local diameter remains substantially constant over the entire height of the wire semiconductor stack 10. In other words, the collector portion 11, the base portion 12 and the emitter portion 13 have substantially the same local diameter. This configuration can allow to optimize the collector current I_{c}.

Alternatively, the local diameter may not be constant over the entire height of the wire semiconductor stack 10. Thus, it is possible, for example, for the emitter portion 13 to have an average diameter smaller than that of the collector portion 11, and for the base portion 12 to have a variation in the local diameter to switch from the diameter of the emitter portion 13 to that of the collector portion 11. This configuration can allow to reduce the recombination rate of the electrons near the injection of holes by the extrinsic base layer 6.

The collector portion 11 extends on and in contact with the non-silicided part 3.1 (nucleation zone) of the extrinsic collector layer 3. It extends longitudinally along the longitudinal axis Z. It is preferably made of the same monocrystalline semiconductor material as that of the extrinsic collector layer 3 (that of the substrate). In this example, it is made of monocrystalline silicon. The material is N-doped in the case of an NPN transistor.

The base portion 12 extends on and in contact with the collector portion 11. It extends longitudinally along the longitudinal axis Z. It is made of a crystalline semiconductor material, such as silicon or silicon germanium, preferably monocrystalline. In this example in which the transistor is homojunction, it is made of monocrystalline silicon. The material is P-doped in the case of an NPN transistor. In the case of an heterojunction type (HBT) transistor, the material can be a silicon germanium, preferably monocrystalline. The vertical profile of germanium concentration can have a triangular shape, as described in the article by Panda et al. entitled “SiGe-based Nanowire HBT for THz Applications,” 2023 7th IEEE Electron Devices Technology & Manufacturing Conference (EDTM), Seoul, Republic of Korea, 2023, pp. 1-3 (incorporated herein by reference). It can have other types of variation.

The emitter portion 13 extends on and in contact with the base portion 12. It extends longitudinally along the longitudinal axis Z. It is made of a crystalline, preferably monocrystalline, semiconductor material, for example the same material as that of the collector portion 11. In this example, it is made of monocrystalline silicon. The material is strongly N-doped in the case of an NPN transistor.

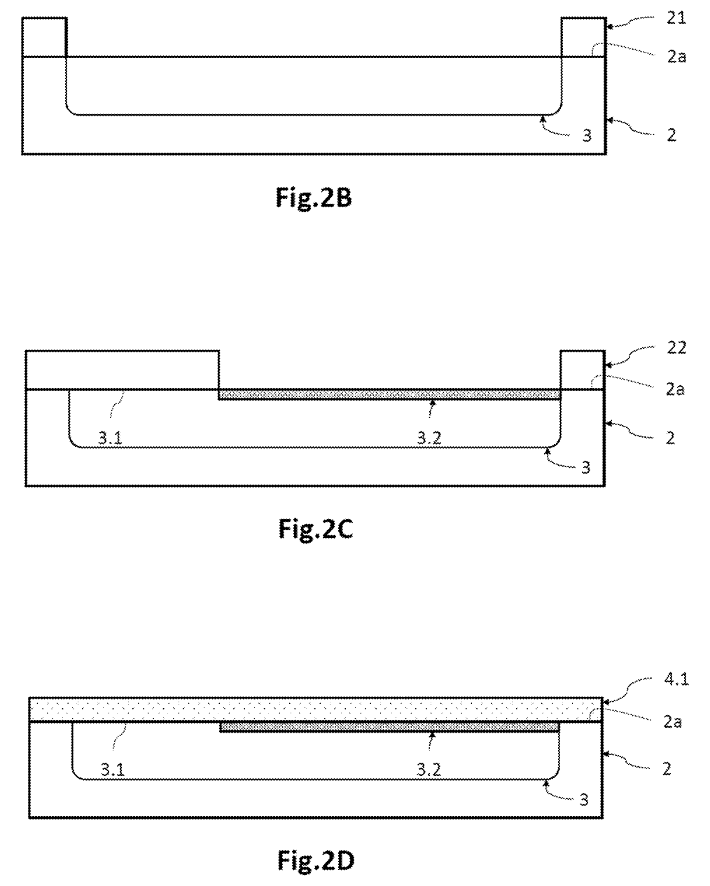

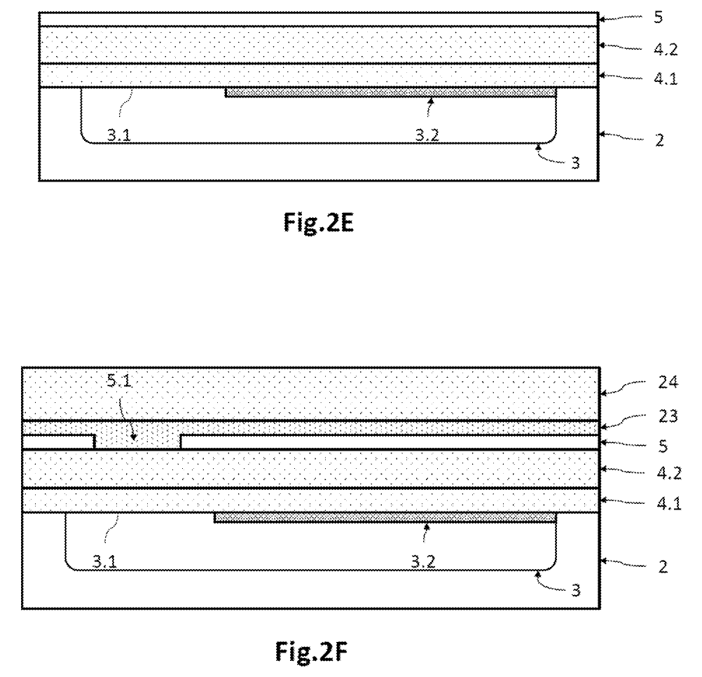

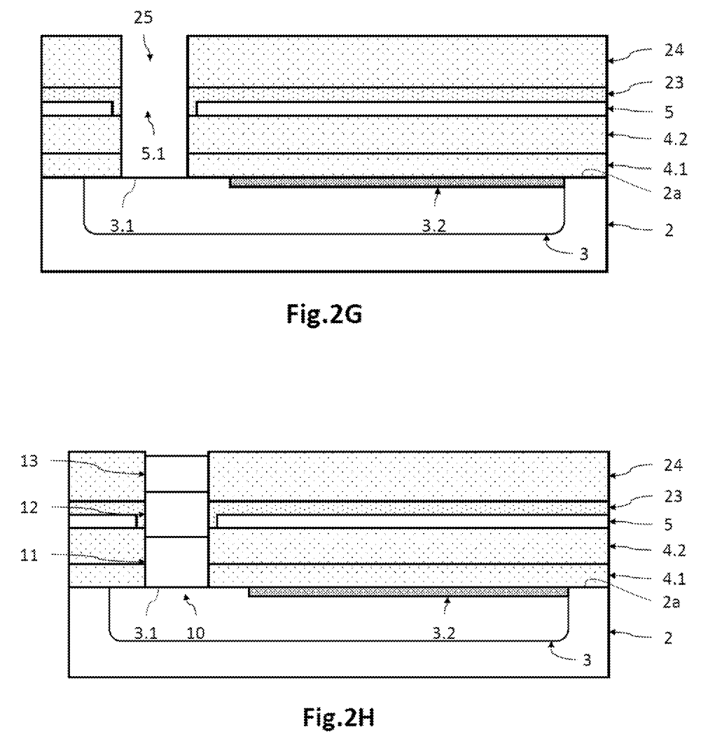

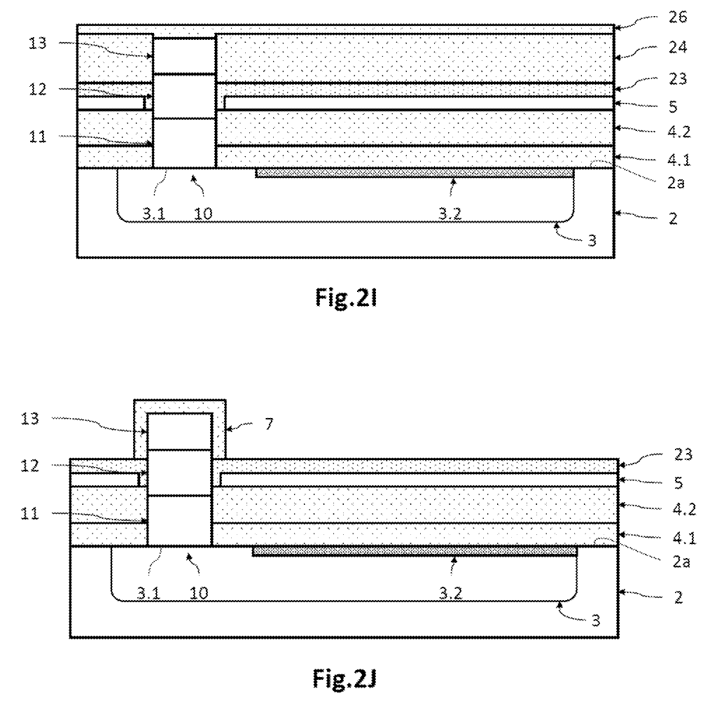

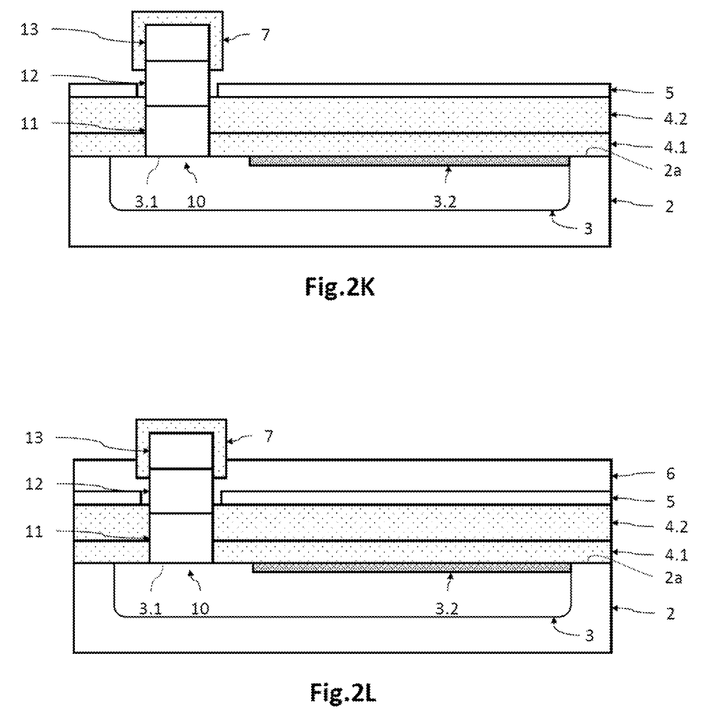

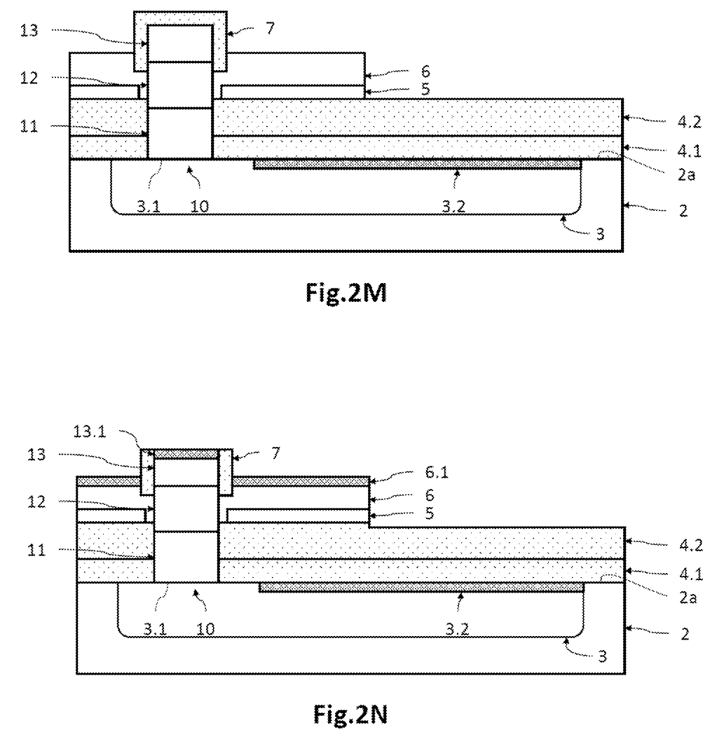

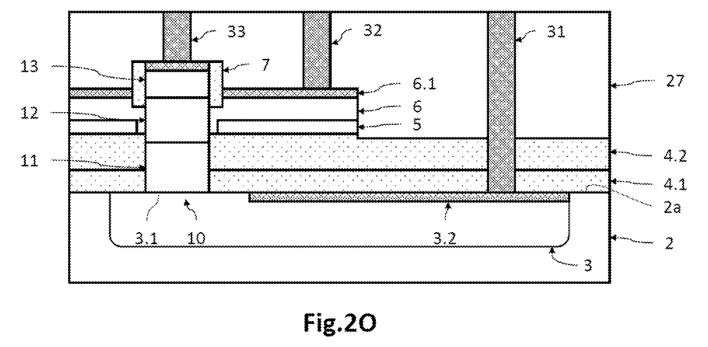

The wire semiconductor stack 10 is located in a vertical cavity 25 (through-hole, cf. FIG. 2G) formed in a stack of layers.

Thus, a lower insulating layer 4.1, 4.2 extends over the substrate 2 and the extrinsic collector layer 3. It is formed from an electrically insulating material such as silicon oxide. This lower insulating layer 4.1, 4.2 surrounds in the plane XY and is in contact with the lateral edge of the collector portion 11, preferably over its entire periphery.

It also surrounds in the plane XY and is in contact with a lower part of the lateral edge of the base portion 12 along its entire periphery. Thus, the lower insulating layer (formed by the sublayers 4.1, 4.2) has a thickness along the axis Z which is slightly greater than the height of the collector portion 11 to contact fully here the collector portion 11 and contact a bottom part of the base portion 12.

In this example, the lower insulating layer is formed by a first insulating layer 4.1, located in contact with the substrate 2 and the extrinsic collector layer 3, and a second insulating layer 4.2, which covers the first. The layer 4.1 can be a deposited silicon oxide, and the layer 4.2 can be a silicon oxide transferred and assembled by direct bonding to the layer 4.1. This transferred and bonded oxide can be a buried oxide layer (BOX) of an SOI substrate. Alternatively, the lower insulating layer can be the same oxide layer created by deposition.

Then, an epitaxial regrowth layer 5 (also called nucleation layer) rests on the lower insulating layer, here on the layer 4.2. It surrounds in the plane XY the base portion 12, preferably along its entire periphery, while being laterally spaced apart therefrom. In other words, in the plane XY, a space is present between the lateral edge of the base portion 12 and the lateral edge facing it of the epitaxial regrowth layer 5. This layer is made of a crystalline semiconductor material, allowing the creation by selective epitaxy of the extrinsic base layer 6. It is preferably monocrystalline. The monocrystalline nature of the epitaxial regrowth layer 5 allows high-quality selective epitaxial growth of the extrinsic base and reduces the base access resistance. This can be a layer made of silicon or made of silicon germanium. The material can be unintentionally doped or be P-doped here.

The extrinsic base layer 6 rests on the one hand on and in contact with the epitaxial regrowth layer 5. On the other hand, it surrounds in the plane XY the base portion 12, preferably over its entire periphery, while being in contact with the lateral edge thereof. It is formed from a crystalline semiconductor material, here made of silicon insofar as the bipolar transistor 1 is homojunction. It can be made of silicon germanium in the case of an SiGe HBT transistor.

In the case in which the base portion 12 and the epitaxial regrowth layer 5 are made of monocrystalline materials, the extrinsic base layer 6 can then be monocrystalline at the interface with the base portion 12, and can also be monocrystalline at the interface with the epitaxial regrowth layer 5. It can be polycrystalline in a connection zone located between the epitaxial regrowth layer 5 and the upper insulating portion 7.

An upper insulating portion 7 surrounds in the plane XY and is in contact with the lateral edge of the emitter portion 13, along its entire periphery. It is made of an electrically insulating material, such as a silicon oxide. In addition, it extends over a top part of the lateral edge of the base portion 12. Thus, it prevents contact between the extrinsic base layer 6 and the emitter portion 13. It thus forms a protective shell located at the head of the wire.

Thus, the extrinsic base layer 6 is in contact with the base portion 12 only over a central part of the height of its lateral edge, thus avoiding any electrical contact between the extrinsic base layer 6 and the collector portion 11 on the one hand, and the emitter portion 13 on the other hand. Indeed, the lower insulating layer 4.2 also extends over a lower part of the lateral edge of the base portion 12, thus preventing contact between the extrinsic base layer 6 and the collector portion 11. And the upper insulating portion 7 extends over a top part of the lateral edge of the base portion 12, thus preventing contact between the extrinsic base layer 6 and the emitter portion 13. As a result, the extrinsic base layer 6 is in contact only with a central part of the lateral edge of the base portion 12 and is not therefore in contact with the base portion 12 over its entire height.

Finally, according to one embodiment, silicided areas are present so as to reduce the contact resistance. The extrinsic collector layer 3 has a silicided part 3.2 of the upper face 2a, where a collector contact 31 comes in contact. This silicided part 3.2 is located at a distance, in the plane XY, from the non-silicided part 3.1 where the wire semiconductor stack 10 rests.

The extrinsic base layer 6 has a silicided part 6.1 of its upper face, where a base contact 32 comes in contact.

The emitter portion 13 includes a silicided part 13.1 of its upper face, where an emitter contact 33 comes in contact.

The collector 31, base 32, and emitter 33 contacts are made of an electrically conductive material, for example one or more metals. They vertically cross a filling layer 27 made of an electrically insulating material, to come in contact with the corresponding silicided parts 3.2, 6.1, 13.1. This filling layer 27 extends in the plane XY so as to cover the bipolar transistor 1 (the semiconductor stack 10, the extrinsic base layer 6 and the lower insulating layer 4.1, 4.2).

Thus, the bipolar transistor 1 has a wire configuration, in which the electrical contacts of the collector 11, base 12 and emitter 13 portions are made on the front face, that is to say on the side opposite to the substrate 2. In addition, the electrical contact of the collector portion 11 is made by means of an extrinsic collector layer 3, made here from a preferably monocrystalline silicon. This bipolar transistor 1 can be created by usual techniques in microelectronics (deposition of layers, localized etching, transfer and bonding, etc.).

It is recalled that this bipolar transistor 1 can be homojunction or heterojunction. It can also be of the NPN type or PNP type.

Moreover, according to one embodiment, the bipolar transistor 1 can have a structure symmetrical with respect to a vertical axis passing through the center of the wire semiconductor stack 10. It can thus include collector 31 and base 32 contacts located symmetrically with respect to this vertical axis.

The collector 11, base 12, and emitter 13 portions can be made of a monocrystalline material, thus improving the performance of the bipolar transistor 1. Moreover, the transverse dimensions of the collector 11, base 12, and emitter 13 portions can be constant over the entire height of the wire semiconductor stack 10, which also contributes to improving performance.

FIGS. 2A-2Q illustrate various steps of a method for manufacturing an integrated circuit including bipolar transistors in a wire configuration, according to one embodiment. In this example, like in FIG. 1, a single transistor is shown. Here this is a homojunction transistor of the NPN type, but it could be of the PNP type, and could also be heterojunction, for example of the Si/SiGe type.

In reference to FIG. 2A, a substrate 2 is made out of monocrystalline silicon. As indicated above, it can be unintentionally doped or be slightly P- or N-doped. It has a flat upper face 2a.

In reference to FIG. 2B, the extrinsic collector layer 3 is created. Here this is an N-doped region of the substrate 2, created by ion implantation of dopants in a localized manner, via an implantation mask 21. The extrinsic collector layer 3 is flush with the upper face 2a.

In reference to FIG. 2C, a silicided part 3.2 of the extrinsic collector layer 3 is created, at the upper face 2a, while keeping a non-silicided part 3.1 at this same upper face 2a.

For this, a mask 22 is deposited on the substrate 2, so as to cover one part of the extrinsic collector layer 3 and expose another part. The silicidation can be carried out in a conventional manner, for example by the deposition of a layer of a metal, followed by one or more rapid annealing operations, and finally the removal of the metal that has not reacted.

In reference to FIG. 2D, a first insulating layer 4.1, here made of a silicon oxide, is deposited so as to cover the substrate 2 and the extrinsic collector layer 3, at both the non-silicided part 3.1 and the silicided part 3.2. A chemical mechanical planarization step can be carried out to obtain a flat upper face.

In reference to FIG. 2E, a second insulating layer 4.2, here made of silicon oxide, is assembled by transfer and direct bonding of the oxide/oxide type. For this, a stack, formed by the epitaxial regrowth layer 5, here made of monocrystalline silicon, and the second insulating layer 4.2, is transferred onto the first insulating layer 4.1. This stack can come from a Silicon On Insulator (SOI) substrate. The two insulating layers 4.1, 4.2 are placed in contact and assembled by direct bonding.

It is recalled that, alternatively, a single insulating layer can have been deposited on the substrate 2, then an epitaxial regrowth layer can then be deposited on the insulating layer. The epitaxial regrowth layer can for example be made of polycrystalline or amorphous silicon.

In reference to FIG. 2F, a window 5.1 (through-hole) is made in the epitaxial regrowth layer 5, by localized etching, this window 5.1 being intended to allow the creation of a cavity 25 in which the wire semiconductor stack 10 will be created (see FIG. 2G).

A sacrificial layer 23 is then deposited so as to cover the epitaxial regrowth layer 5 and fill the window 5.1. It can be made of a silicon nitride. A chemical mechanical planarization step can then be carried out so as to obtain a flat upper face. This sacrificial layer 23 is made of a material which can be selectively removed by isotropic chemical etching. In other words, the chemical agent used will only remove this sacrificial layer 23, without removing the silicon or the oxide present.

Finally, an upper insulating layer 24 is deposited so as to cover the sacrificial layer 23. This layer is made of an electrically insulating material, here an oxide. It is intended to allow the selective epitaxy of the portions 11, 12 and 13 in the cavity 25 (cf. FIG. 2G), and to subsequently form the protective shell 7 of the transmitter portion 13 (cf. FIG. 2J).

In reference to FIG. 2G, a cavity 25 (through-hole) is created which extends vertically through the upper insulating layer 24, the sacrificial layer 23, and the two insulating layers 4.2, 4.1 to open onto the non-silicided part 3.1 of the extrinsic collector layer 3 at the upper face 2a. The cavity 25 is thus located in the window 5.1 defined by the epitaxial regrowth layer 5.

In reference to FIG. 2H, the wire semiconductor stack 10 is created in the cavity 25, by epitaxial growth. First, the collector portion 11 is created, by epitaxy starting from the non-silicided part 3.1 of the extrinsic collector layer 3, then the base portion 12, and finally the emitter portion 13.

The epitaxial growth here is a selective epitaxy, insofar as the crystalline material of the wire semiconductor stack 10 only grows from the material (here monocrystalline silicon) of the extrinsic collector layer 3, and not from the layers of oxide or nitride.

The deposition can be carried out by chemical vapor deposition, for example at reduced pressure (LPCVD, for Low Pressure Chemical Vapor Deposition) or at rapid temperature (RTCVD, for Rapid Thermal Chemical Vapor Deposition), among others. It should be noted that this epitaxy of the collector 11, base 12, and emitter 13 portions can be carried out during the same continuous epitaxy step, which contributes to improving the crystalline quality of the material.

The collector portion 11 is thus first formed by epitaxy starting from the non-silicided part 3.1 made of monocrystalline silicon of the extrinsic collector layer 3. Its height is less than the cumulative thickness of the two insulating layers 4.1, 4.2. Thus, the entire lateral edge of the collector portion 11 is in contact, over its entire periphery, by the oxide of the insulating layers 4.1, 4.2.

The base portion 12 is then formed by epitaxy starting from the upper face of the collector portion 11. Its height is such that its lateral edge is in contact over its entire periphery, first with the second insulating layer 4.2, then with the sacrificial layer 23 over its entire thickness, and finally with a part of the upper insulating layer 24.

The emitter portion 13 is finally formed by epitaxy starting from the upper face of the base portion 12. Its height is such that its lateral edge is entirely in contact, over its entire periphery, with the upper insulating layer 24.

In reference to FIG. 2I, an additional insulating layer 26, here an oxide, is deposited so as to cover the upper insulating layer 24, as well as the emitter portion 13. A planarization can be carried out to obtain a flat upper face.

In reference to FIG. 2J, the upper insulating portion 7 is created. For this, anisotropic localized etching of the upper insulating layer 24 and of the additional insulating layer 26 is carried out to only keep the portion that surrounds the head of the wire semiconductor stack 10, and more precisely the emitter portion 13, and which covers this portion. A surface of the sacrificial layer 23 is therefore freed (i.e., exposed).

In reference to FIG. 2K, the sacrificial layer 23 is removed, by chemical selective etching. The etching agent only removes the sacrificial layer 23 and remains inert with respect to the oxide of the upper insulating portion 7, the silicon of the epitaxial regrowth layer 5, the material of the base portion 12, and the oxide of the second insulating layer 4.2. Thus, the upper face of the epitaxial regrowth layer 5 is freed, as well as the central part of the lateral edge of the base portion 12.

In reference to FIG. 2L, the extrinsic base layer 6 is created by epitaxy starting from the free (i.e., exposed) surface of the base portion 12 on the one hand, and from the free surface of the epitaxial regrowth layer 5 on the other hand.

It is made of a semiconductor material P-doped here. The material is preferably chosen to be monocrystalline at the interface with the base portion 12 and at the interface with the epitaxial regrowth layer 5. At the junction between these two zones, the material can be polycrystalline. The epitaxial regrowth layer 5 can have a thickness such that it surrounds the upper insulating portion 7 over a part of its height.

In reference to FIG. 2M, the extrinsic base layer 6 and the epitaxial regrowth layer 5 are etched locally to only keep a part that surrounds and is in contact with the wire semiconductor stack 10. A part of the upper face of the second insulating layer 4.2 is thus freed.

In reference to FIG. 2N, a silicidation of the upper face of the extrinsic base layer 6 is carried out. A silicidation of the upper face of the emitter portion 13 is also carried out.

For this, the part of the upper insulating portion 7 that covers the emitter portion 13 can be removed by an anisotropic dry etching, to free its upper face. The silicidation can then be carried out. It should be noted that during this dry etching step, a part of the second insulating layer can be slightly etched.

A silicided part 6.1 of the extrinsic base layer 6 and a silicided part 13.1 of the emitter portion 13 are thus obtained.

In reference to FIG. 2O, the manufacturing of the bipolar transistor 1 is finalized. The assembly is covered by a filling layer 27 made of an electrically insulating material, for example a nitride and/or a silicon oxide. A planarization can be carried out to obtain a flat upper face. A collector contact 31, a base contact 32, and an emitter contact 33 are created, which vertically cross the filling layer 27, and come in contact, respectively, with the silicided part 3.2 of the extrinsic collector layer 3, with the silicided zone 6.1 of the extrinsic base layer 6, and finally with the silicided part 13.1 of the emitter portion 13.

Thus, a bipolar transistor 1 in a wire configuration, the intrinsic parts of which are formed by the collector 11, base 12, and emitter 13 portions of the wire semiconductor stack 10, and which includes a lower extrinsic collector layer 3, and an intermediate extrinsic base layer 6, is obtained. This bipolar transistor was created by conventional microelectronics techniques (deposition of layers, localized etching, etc.).

The crystalline quality of the collector 11, base 12, and emitter 13 portions is good insofar as they can have been made from one or more monocrystalline materials. The material of the intermediate extrinsic base layer 6 can also be monocrystalline over a part of its volume, in particular at the interface with the base portion 12, which improves the performance of the transistor.

Embodiments have just been described. Various alternatives and modifications will appear to a person skilled in the art.

1. A bipolar transistor, including:
a substrate made of a crystalline semiconductor material and having an upper face;
a lower doped region located in the substrate and flush with the upper face of the substrate;
a semiconductor stack, having a three-dimensional wire shape, extending from the substrate and successively comprising:
a collector portion resting on and in contact with the lower doped region;
a base portion resting on and in contact with the collector portion; and
an emitter portion resting on and in contact with the base portion;
a lower insulating layer resting on the substrate and at least partly surrounding and in contact with a lateral edge of the collector portion;
an intermediate doped layer, made of a crystalline semiconductor material, resting on the lower insulating layer and at least partly surrounding and in contact with a lateral edge of the base portion; and
an upper insulating portion at least partly surrounding and in contact with a lateral edge of the emitter portion.

2. The bipolar transistor according to claim 1, wherein the lower doped region and the semiconductor stack are made of monocrystalline semiconductor material.

3. The bipolar transistor according to claim 1, wherein the lower doped region, the semiconductor stack, and the intermediate doped layer are made from silicon.

4. The bipolar transistor according to claim 1, further comprising an epitaxial regrowth layer resting on the lower insulating layer and surrounding the base portion while being spaced apart laterally therefrom, wherein the epitaxial regrowth layer is made of a crystalline semiconductor material, and wherein the intermediate doped layer is resting on and in contact with the epitaxial regrowth layer.

5. The bipolar transistor according to claim 4, wherein the epitaxial regrowth layer is made of a monocrystalline semiconductor material.

6. The bipolar transistor according to claim 1, wherein the lower insulating layer is in contact with the collector portion over its entire height and its entire periphery, and wherein the lower insulating layer is in contact with a lower part of the lateral edge of the base portion over its entire periphery, the intermediate doped layer thus being electrically insulated from the collector portion.

7. The bipolar transistor according to claim 1, wherein the upper insulating portion is in contact with the emitter portion over its entire height and its entire periphery, and wherein the upper insulating portion is in contact with an upper part of the lateral edge of the base portion over its entire periphery, the intermediate doped layer thus being electrically insulated from the emitter portion.

8. The bipolar transistor according to claim 1, wherein the semiconductor stack providing the three-dimensional wire shape has a constant transverse dimension over its entire height.

9. The bipolar transistor according to claim 1, further comprising:
a filling layer made of an electrically insulating material;
a collector contact extending through the filling layer and in contact with the lower doped region;
a base contact extending through the filling layer and in contact with the intermediate doped layer; and
an emitter contact extending through the filling layer and in contact with the emitter portion.

10. The bipolar transistor according to claim 8, wherein:
the lower doped region includes, on its upper face, a non-silicided part on which the semiconductor stack is in contact, and a silicided part on which the collector contact is in contact;
the intermediate doped layer has, on its upper face, a silicided part on which the base collector is in contact; and
the emitter portion has, on its upper face, a silicided part on which the emitter collector is in contact.

11. The bipolar transistor according to claim 1, wherein the base portion is made from silicon-germanium.

12. An integrated circuit, including a plurality of said bipolar transistors according to claim 1.

13. A method for manufacturing a bipolar transistor, including the following steps:
creating a lower doped region located in a substrate made of a crystalline semiconductor material and having an upper face that is flush with the upper face of the substrate;
creating a lower insulating layer on the substrate and the lower doped region;
creating an epitaxial regrowth layer resting on the lower insulating layer and having a through-hole;
creating a sacrificial layer covering the epitaxial regrowth layer and the through-hole;
creating an upper insulating layer covering the sacrificial layer;
creating a cavity extending down to the lower doped region and passing through the through-hole;
epitaxially growing a semiconductor stack in the cavity, said stack having a three-dimensional wire shape, said stack extending from the substrate and successively comprising: a collector portion resting on and in contact with the lower doped region; a base portion resting on and in contact with the collector portion; and an emitter portion resting on and in contact with the base portion;
creating, by localized etching of the upper insulating layer, an upper insulating portion at least partly surrounding and in contact with a lateral edge of the emitter portion, wherein the upper insulating layer is completed so as to cover the emitter portion;
selectively removing the sacrificial layer to free a surface of the epitaxial regrowth layer and a surface of the base portion; and
epitaxially growing, starting from the free surface of the epitaxial regrowth layer and the free surface of the base portion, an intermediate doped layer made of a crystalline semiconductor material.

14. The manufacturing method according to claim 13, wherein the epitaxial regrowth layer is made of a monocrystalline semiconductor material.

15. The manufacturing method according to claim 13, wherein epitaxially growing a semiconductor stack comprises performing a single epitaxy step.

16. The manufacturing method according to claim 13, further comprising, during the step of creating the lower insulating layer: depositing a first sub-layer on the substrate and the lower doped region; then transferring a second sub-layer to be bonded to the first sub-layer, the second sub-layer being coated on its opposite face by the epitaxial regrowth layer which is made of a monocrystalline material.

17. The manufacturing method according to claim 13, further including the following steps:
creating, on an upper face of the lower doped region, a non-silicided part on which the semiconductor stack is in contact and a silicided part;
creating, on an upper face of the intermediate doped layer, a silicided part;
creating, on an upper face of the emitter portion, a silicided part;
creating a filling layer, made of an electrically insulating material, covering the semiconductor stack, the intermediate doped layer and the lower insulating layer;
creating, through the filling layer, a collector contact coming in contact with the silicided part of the lower doped region, a base contact coming in contact with the silicided part of the
intermediate doped layer, and an emitter contact coming in contact with the silicided part of the emitter portion.
